(19) United States
(12) Patent Application Publication
(10) Pub. No.: US 2023/0331559 A1
(43) Pub. Date: Oct. 19, 2023

(54) EXPLOSIVE COMPOSITION FOR DIAMOND SYNTHESIS

(71) Applicant: DAICEL CORPORATION, Osaka-shi, Osaka (JP)

(72) Inventors: Akihiko TSURUI, Tokyo (JP); Masahiro NISHIKAWA, Tokyo (JP); Tomoaki MAHIKO, Tokyo (JP); Ming LIU, Tokyo (JP)

(73) Assignee: DAICEL CORPORATION, Osaka-shi, Osaka (JP)

(21) Appl. No.: 17/908,338

(22) PCT Filed: Mar. 11, 2021
(86) PCT No.: PCT/JP2021/009802

§ 371 Date: Aug. 31, 2022

(30) Foreign Application Priority Data
Mar. 27, 2020 (JP) 2020-057636

(51) Int. Cl. C06B 25/34; C01B 32/26; C06B 25/08

(52) U.S. Cl. CPC C01B 32/26; C06B 25/08; C06B 25/34

(57) ABSTRACT

Provided is an explosive composition for diamond synthesis by which diamond particles having a relatively large diameter can be produced. The explosive composition for diamond synthesis contains an explosive component, a carbon raw material that may be included as the explosive component, and diamond particles. Furthermore, the total proportion of the explosive component, the carbon raw material, and the diamond particles relative to the total amount of the explosive composition for diamond synthesis is 99 mass% or greater. The crystallite diameter of primary particles of the diamond particles as determined by the XRD method is preferably 100 nm or less.

### TECHNICAL FIELD

The present disclosure relates to an explosive composition for diamond synthesis. The present disclosure also relates to an explosive body obtained using the explosive composition for diamond synthesis, and to a method for producing diamond particles using the explosive body. The present application claims priority to JP 2020-057636 filed in Japan on Mar. 27, 2020, the content of which is incorporated herein.

### BACKGROUND ART

In recent years, the development of particulate diamond materials called nanodiamonds has advanced. A detonation method is known as a nanodiamond synthesis method. In the detonation method, for example, an explosive is exploded in a sealed container, the explosive components that are used undergo partially incomplete combustion and release carbon, and with this carbon being used as a raw material, nanodiamonds are produced by the action of the pressure and energy of the shock waves that are produced in the explosion. Technology relating to a detonation method like this is described, for example, in Patent Documents 1 to 3 listed below.

### CITATION LIST

### Patent Document

Patent Document 1: JP 2005-289677 A
Patent Document 2: JP 2014-144903 A
Patent Document 3: JP 2016-113310 A
Patent Document 4: JP 02-241536 A
Patent Document 5: WO 2007/001031

### SUMMARY OF INVENTION

### Technical Problem

On the other hand, in applications requiring advanced characteristics such as fluorescence characteristics and magnetic characteristics of nitrogen-vacancy centers incorporated in nanodiamonds, the demand for controlling the primary particle size of nanodiamonds is increasing. For example, with regard to fluorescent characteristics, nanodiamond particles with a larger size are assumed to be advantageous for an excited state for emitting fluorescence. Therefore, a demand exists for technology for producing nanodiamonds having a relatively large diameter.

However, although the yield of nanodiamonds has been remarkably improved by optimizing the production method, there have not been many developments of technology for controlling particle size. The particle size of nanodiamonds obtained through a detonation method is thought to depend on the temperature and pressure at the time of the detonation. However, since the detonation velocity of the explosive is unchanged as a characteristic of each explosive in a mixture, there is almost no control of the particle size of the nanodiamonds.

Note that while Patent Document 4 indicates that the production yield of diamonds is increased by using a molded product that is molded from an explosive composition obtained by blending a diamond powder and paraffin into an explosive component, Patent Document 4 does not indicate that diamonds having a relatively large diameter are obtained. Additionally, Patent Document 5 discloses the use of a molded article of an explosive composition, the molded article being obtained by adding an adamantane diol to an explosive component, mixing, and then filling a mold with the mixture in a molten state. However, Patent Document 5 also indicates that through this method, ultrafine single crystal diamonds having an average particle size smaller than that of crystal diamonds obtained by a known method are obtained.

Therefore, an object of the present disclosure is to provide an explosive composition for diamond synthesis by which diamond particles having a relatively large diameter can be produced. Another object of the present disclosure is to provide a method for producing the diamond particles having a relatively large diameter.

### Solution to Problem

As a result of diligent research to achieve the objects described above, the inventors of the present disclosure discovered that diamond particles having a relatively large diameter can be produced using an explosive composition having diamond particles embedded as seed crystals, in which the proportion of an explosive component, a carbon raw material, and the diamond particles is large. The inventors also discovered that diamond particles having a relatively large diameter can be produced using an explosive body having diamond particles or adamantanes embedded as seed crystals and molded through a press-loading method. The inventors arrived at the invention of the present disclosure on the basis of these findings.

The present disclosure provides an explosive composition for diamond synthesis, the explosive composition containing an explosive component, a carbon raw material that may be included as the explosive component, and diamond particles, wherein a total proportion of the explosive component, the carbon raw material, and the diamond particles relative to a total amount of the explosive composition for diamond synthesis is 99 mass% or greater.

A crystallite diameter of primary particles of the diamond particles as determined by an XRD method is preferably 100 nm or less.

The diamond particles may include cluster diamonds. Moreover, the diamond particles preferably include detonation diamond particles.

The explosive component preferably includes an explosive component that serves as the carbon raw material.

The explosive component that serves as the carbon raw material preferably includes a compound having a nitro group.

The diamond particles are preferably contained at an amount of 15 parts by mass or less per 100 parts by mass of the total amount of the explosive component.

The explosive component preferably includes 2,4,6-trinitrotoluene and cyclotrimethylenetrinitramine. A mass ratio of 2,4,6-trinitrotoluene to cyclotrimethylenetrinitramine [2,4,6-trinitrotoluene/cyclotrimethylenetrinitramine] in the explosive component is preferably from 30/70 to 95/5.

The present disclosure also provides an explosive body for diamond synthesis, the explosive body being a compressed filler of the above-mentioned explosive composition for diamond synthesis.

The present disclosure also provides an explosive body for diamond synthesis, the explosive body being a compressed filler of an explosive composition containing an explosive component, a carbon raw material that may be included as the explosive component, and an adamantane.

Further, the present disclosure also provides a method for producing diamond particles, the method including detonation in which the explosive component in the explosive body for diamond synthesis is exploded to obtain diamond particles having a larger diameter than that of diamond particles obtained without blending the diamond particles or the adamantane as seed crystals.

The diamond particles obtained through the detonation preferably include single crystal diamonds.

### Advantageous Effects of Invention

According to the explosive composition for diamond synthesis and the explosive body for diamond synthesis of the present disclosure, diamond particles can be produced with a relatively larger diameter than in a case in which diamond particles are not embedded as seed crystals.

### DESCRIPTION OF EMBODIMENTS

### Explosive Composition

An explosive composition for diamond synthesis (hereinafter, may be referred to simply as an “explosive composition”) according to one embodiment of the present disclosure contains at least an explosive component, a carbon raw material, and diamond particles as seed crystals. The carbon raw material may be included as the explosive component. In this case, the explosive composition may or may not include a carbon raw material in addition to the explosive component.

When the explosive body formed from the explosive composition is subjected to a detonation method and the explosive component is exploded, the diamond particles act as seed crystals, diamonds are formed through detonation of the carbon raw material, the seed crystals are grown, and diamond particles having a larger diameter than that of diamond particles obtained in a case in which seed crystal particles are not embedded in the explosive body composition can be obtained. It is assumed that this occurs because the generation of new diamond seed crystals produced from the carbon raw material is suppressed by blending diamond particles as seed crystals into the explosive composition in advance, and diamonds derived from the carbon raw material are formed on the surface of the diamond particles serving as the seed crystals.

Examples of the explosive component include preferably a compound having a nitro group (nitro compound), and more preferably a compound having three or more nitro groups. Examples of such nitro compounds include an aromatic nitro compound (preferably a tri- or tetra-nitrobenzene optionally substituted with an amino group and/or a methyl group), a nitramine (preferably, a C₃₋₆ alkyl (3-6 nitro)amine), and nitrates. Specific examples include cyclotrimethylenetrinitramine (RDX), that is, hexogen; 2,4,6-trinitrotoluene (TNT); 2,4,6-trinitrophenylmethylnitramine; cyclotetramethylenetetranitramine, that is, octogen; nitroguanidine; pentaerythritol tetranitrate (PENT); diazodinitrophenol (DDNP); tetryl(tetranitromethylaniline); and tetramethylene tetranitramine (HMX). A single explosive component may be used, or two or more may be used.

The explosive component preferably includes an explosive component as the carbon raw material. Examples of such explosive components include aromatic compounds having three or more nitro groups, and of these, TNT is preferable. TNT and RDX are particularly preferably included as the explosive component. TNT is effective as a carbon raw material, and RDX tends to contribute greatly to increasing the particle size of the resulting diamond particles. In this case, the mass ratio of TNT to RDX (TNT/RDX) is, for example, in the range from 30/70 to 95/5, preferably from 40/60 to 90/10, more preferably 51/49 to 80/20, and further preferably from 55/45 to 70/30. When the mass ratio is 95/5 or less (particularly, less than or equal to 80/20), the mass ratio of RDX is large, the detonation velocity of TNT is increased by RDX, and diamond particles having a large diameter tend to be easily obtained. Furthermore, when the mass ratio is within the range described above, the yield of the diamond particles tends to be high.

The content ratio of the explosive component in the explosive composition is preferably 60 mass% or higher, more preferably 70 mass% or higher, and even more preferably 90 mass% or higher relative to the total amount (100 mass%) of the explosive composition.

The explosive composition also contains at least diamond particles as the seed crystals. A single type of diamond particles may be used, or two or more types may be used.

The diamond particles used as the seed crystals are preferably nano-sized diamond particles (nanodiamond particles), and known or commonly used nanodiamond particles can be used. The nanodiamond particles may be nanodiamond particles for which the nanodiamond surface is modified (surface-modified nanodiamond particles), or may be nanodiamond particles that are not surface-modified. Nanodiamond particles that are not surface-modified have a hydroxyl group (-OH) on the surface. A single type of diamond particles may be used, or two or more types may be used.

The diamond particles preferably contain primary diamond particles. In addition, the diamond particles may contain secondary particles in which a plurality of the primary particles are agglomerated (aggregated).

As the diamond particles, for example, detonation diamond particles (that is, diamond particles produced by a detonation method) and high-temperature high-pressure diamond particles (that is, diamond particles produced by a high-temperature high-pressure method) can be used. Of these, detonation diamond particles are preferable from the perspective of obtaining single crystal diamonds with the primary particles having a small particle size on a single digit nanometer scale.

Examples of the detonation diamond particles include air-cooled detonation diamond particles (that is, diamond particles produced by an air-cooled detonation method) and water-cooled detonation diamond particles (that is, diamond particles produced by a water-cooled detonation method). Among these, air-cooled detonation diamond particles are preferable in that the primary particles thereof are smaller than those of water-cooled detonation diamond particles.

The crystallite diameter, obtained through X-ray diffraction (XRD method), of the primary particles of the diamond particles is preferably 100 nm or less, more preferably 50 nm or less, even more preferably 10 nm or less, and particularly preferably 7 nm or less. The lower limit of the crystallite diameter is, for example, 1 nm, and may be 4 nm. When the primary particles of the diamond particles have the crystallite diameter described above, the particle size of the diamond particles obtained through the detonation method using the explosive composition is likely to be larger.

The content of the diamond particles in the explosive composition is preferably 15 parts by mass or less, more preferably 10 parts by mass or less, and even more preferably 5 parts by mass or less per 100 parts by mass of the total amount of the explosive component. When the content thereof is small, the amount of carbon raw material per one seed crystal increases, and therefore the particle size of the diamond particles obtained by the detonation method using the explosive composition tends to be larger. In particular, when the content thereof is 15 parts by mass or less, diamond particles with a large particle size are more likely to be obtained. From the perspective of increasing the number of diamond particles that are obtained, the content is, for example, 0.05 parts by mass or greater and preferably 0.08 parts by mass or greater.

As the carbon raw material, another carbon raw material in addition to the explosive component acting as a carbon raw material may be contained. Examples of the other carbon raw material include carbon materials that are known and commonly used in a detonation method, and more specific examples include substituted or unsubstituted alicyclic hydrocarbon compounds, graphite, carbon nanotubes, and fullerenes. Examples of the substituted or unsubstituted alicyclic hydrocarbon compounds include cycloalkanes, such as cyclohexanol, cyclopentanone, and dimethylcyclohexane; adamantane and adamantane derivatives such as adamantanol; and cycloalkenes such as dicyclopentadiene, and norbomene. A single type of that above-mentioned carbon materials may be used, or two or more types may be used.

The explosive composition may include other components in addition to the components described above. Examples of the other components include binder polymers, plasticizers, and anti-aging agents. A single type of each of the other components may be used, or two or more thereof may be used.

In the explosive composition described above, the content proportion (total proportion) of the total of the explosive component, the carbon raw material, and the diamond particles is 99 mass% or higher, preferably 99.5 mass% or higher, and more preferably 99.8 mass% or higher relative to the total amount (100 mass%) of the explosive composition. When the total proportion thereof is 99 mass% or higher, diamond particles having a large diameter can be obtained.

### Explosive Body for Diamond Synthesis

An explosive body for diamond synthesis can be produced using the explosive composition described above. That is, the explosive body for diamond synthesis according to one embodiment of the present disclosure is molded from an explosive composition for diamond synthesis, the explosive composition containing an explosive component, a carbon raw material that may be included as the explosive component, and diamond particles. The total proportion of the explosive component, the carbon raw material, and the diamond particles in the explosive body is preferably within the range exemplified and described as the total proportion in the explosive composition described above.

The explosive body can be produced through, for example, a cast-loading method or a press-loading method (compressing method). In the cast-loading method, a mixture composition is formed containing: a reactive component such as crosslinking agent or a polymerizable component that forms the binder polymer for a case in which the binder polymer is contained; particles of the explosive component; and particles of the diamond particles, and the mixture composition is poured into a mold and then cured to thereby form the explosive body. In the press-loading method, for a case in which the binder polymer is contained, first, the binder polymer dissolved in a solvent, the explosive component particles, and the diamond particles are mixed in water, the solvent is then volatilized from the mixture, and composite particles are produced in a form in which the surface of the explosive component particles is coated with the binder polymer. Next, the composite particles thus produced or the explosive component particles and the diamond particles are pressed while being heated, if necessary, in a press-loading container. In this manner, the explosive body is molded. Of these, when the diamond particles, which are seed crystals, are poured into the mold in the cast-loading method, the diamond particles tend to settle, whereas in the press-loading method, the diamond particles are easily dispersed and arranged in the explosive body, and thus from this perspective, the explosive body is preferably an explosive body (compressed filler) produced through the press-loading method.

In addition, the explosive body for diamond synthesis according to another embodiment of the present disclosure is an explosive body for diamond synthesis molded through the press-loading method from an explosive composition for diamond synthesis containing an explosive component, a carbon raw material that may be included as the explosive component, and an adamantane (that is, the explosive body for diamond synthesis is a compressed filler of the explosive composition for diamond synthesis). When the explosive body is subjected to a detonation method and the explosive component is exploded, the adamantane, which is the smallest skeletal structure of diamonds, act as seed crystals, diamonds are formed through detonation of the carbon raw material, the seed crystals are grown, and diamond particles having a larger diameter than that of diamond particles obtained in a case in which seed crystal particles are not embedded in the explosive body composition can be obtained. It is assumed that this occurs because the generation of new diamond seed crystals produced from the carbon raw material is suppressed by blending adamantane particles as seed crystals into the explosive composition in advance, and diamonds derived from the carbon raw material are formed on the surface of the adamantane particles serving as the seed crystals. A preferred aspect of the explosive body composition containing an adamantane as seed crystals is similar to the above-described preferred aspect of the explosive body composition containing diamond particles as seed crystals. Furthermore, preferred aspects of the content and the crystallite diameter of the primary particles of the adamantane as determined through the XRD method are similar to content and crystallite diameter of the diamond particles described above.

In particular, in the explosive composition containing the adamantane as seed crystals, an explosive component is preferably contained as the above-mentioned carbon raw material. As the explosive component, an aromatic compound having three or more nitro groups is preferred, and among these, TNT is preferable. TNT and RDX are particularly preferably included as the explosive component. TNT is effective as a carbon raw material, and RDX tends to contribute greatly to increasing the particle size of the resulting diamond particles. In this case, the mass ratio of TNT to RDX (TNT/RDX) is, for example, in the range from 30/70 to 95/5, preferably from 40/60 to 90/10, more preferably 51/49 to 80/20, and further preferably from 55/45 to 70/30. When the mass ratio is 95/5 or less (particularly, less than or equal to 80/20), the mass ratio of RDX is large, and the detonation velocity of TNT is increased by RDX, and diamond particles having a large diameter tend to be easily obtained. Furthermore, when the mass ratio is within the range described above, the yield of the diamond particles tends to be high.

Examples of the adamantanes used as the seed crystals include adamantane and adamantane derivatives such as adamantanol. Among these, adamantane is preferable from the perspective of easily obtaining diamond particles with a large particle size. A single type of the adamantanes may be used, or two or more types may be used.

An ignition part is inserted into the explosive body. The ignition part is a member for igniting the explosive body, and is fitted into a hole provided in the explosive body and assembled to the explosive body. The ignition part has a structure in which, for example, a detonator part embedded in the explosive body and a booster part located inside the explosive body and across the outside thereof are adjacently arranged and integrated. Examples of detonators in the detonator part include an instantaneous electric detonator, a stepped electric detonator, an antistatic electric detonator, an electronic delay detonator, and a fuse-type detonator. Examples of boosters in the booster part include highly sensitive explosives containing, as a base material, 2,4,6-trinitrophenylmethylnitramine, pentaerythritol tetranitrate, RDX, and a mixture of TNT and RDX.

### Method for Producing Diamond Particles

The explosive body can be used in diamond synthesis through the detonation method. By implementing the detonation method using the explosive body described above, diamond particles having a larger particle size than that of diamond particles obtained without blending diamond particles or an adamantane as seed crystals can be produced.

The method for producing diamond particles includes exploding the explosive component in the explosive body to obtain diamond particles having a larger diameter than that of diamond particles obtained without blending the seed crystals.

### (Detonation)

Examples of the detonation method used in the above-mentioned detonation include an air-cooled detonation method and a water-cooled detonation method. Among these, the air-cooled detonation method is preferred from the viewpoint of being able to obtain diamond particles having smaller primary particles compared to a case in which the water-cooled detonation method is used. The detonation may be performed in an air atmosphere, or may be performed in an inert gas atmosphere, such as a nitrogen atmosphere, an argon atmosphere, or a carbon dioxide atmosphere.

An embodiment of the air-cooled detonation method is described below. In the above-mentioned detonation implemented using the air-cooled detonation method, first, a molded explosive (explosive body having an ignition part fitted therein) is placed inside a pressure-resistant container for detonation, and the container is sealed in a state where gas of an atmospheric composition at normal pressure and the explosive to be used coexist inside the container. The container is, for example, made of iron, and the volume of the container is, for example, from 0.5 to 40 m³.

In the detonation, an electric detonator, for example, is triggered in the ignition part to detonate the explosive body in the container. “Detonation” refers to an explosion, among those associated with a chemical reaction, wherein a flame surface where the reaction occurs travels at a high speed exceeding the speed of sound. During the detonation, the explosive body that is used causes partially incomplete combustion and releases free carbon, and diamonds are formed from the carbon as a raw material, through the action of the pressure and energy of a shock wave generated in the explosion. At this time, diamonds are generated and adhered to the surface of the seed crystal particles, and thereby diamond particles having a relatively large diameter are formed. Due to Coulomb interaction between crystal planes as well as van der Waals forces between adjacent primary particles or crystallites, the produced diamond particles aggregate very firmly to form aggregates.

Next, the container and the contents of the container are left to stand for approximately 24 hours at room temperature, and thus, are cooled. After the cooling, a diamond particle crude product (containing the aggregates of the diamond particles formed as described above and soot) adhered to the inner wall of the container is scraped off with a spatula, and the diamond particle crude product is thereby collected. The crude product of diamond particles (diamond particle crude product) can be obtained by the method described above. In addition, the desired amount of the diamond particle crude product can be obtained by implementing detonation as described above a necessary number of times.

The primary particle size of the diamond particles obtained through the above-mentioned detonation is larger than the seed crystal particles blended into the explosive composition. The crystallite diameter, determined through X-ray diffraction (XRD method), of the primary particles of the diamond particles obtained through the above-mentioned detonation is larger than the seed crystal particles, and is preferably 100 nm or less, more preferably 50 nm or less, even more preferably 10 nm or less, and particularly preferably 8 nm or less. The lower limit of the crystallite diameter is, for example, 1 nm, and may be 5 nm, 6 nm, or 7 nm.

The BET specific surface area of the primary particles of the diamond particles obtained through the detonation described above is, for example, from 100 to 1000 m²/g, preferably from 150 to 500 m²/g, and even more preferably from 170 to 300 m²/g. Since the diamond particles obtained by the production method described above are relatively large in diameter, diamond particles having a BET specific surface area within the range described above can be obtained.

As an explosion method for producing diamond particles using an explosive, for example, a method (implosion method) is known in which an explosive is exploded in a state of being isolated, through a barrier wall, from a powder mixture obtained by mixing diamond particles and a metal compound, the diamond particles are subjected to a high-temperature, high-pressure environment, and thereby a plurality of diamond particles in the powder mixture are aggregated and integrated, and large diameter diamond particles are obtained. The large diameter diamond particles obtained by the implosion method are produced through the integration of a plurality of diamond particles, and therefore the primary particles become polycrystalline diamond particles. On the other hand, through the above-described detonation using the explosive body, the primary particles of the seed crystals can be grown without integrating the plurality of diamond particles, and thus, single crystal diamonds can be obtained.

### (Acid Treatment)

An acid treatment may be implemented following the detonation described above. In the acid treatment, a strong acid in an aqueous solvent, for example, is allowed to act on the diamond particle crude product, which is a raw material, to remove metal oxides. The diamond particle crude product obtained by the detonation method is prone to include a metal oxide, and the metal oxide is an oxide of Fe, Co, Ni, or the like resulting from the container or the like used in the detonation method. The metal oxide can be dissolved and removed from the diamond particle crude product by allowing a strong acid to act thereon (acid treatment) in an aqueous solvent, for example. The strong acid used in the acid treatment is preferably a mineral acid, and examples thereof include hydrochloric acid, hydrofluoric acid, sulfuric acid, nitric acid, and aqua regia. A single type of the strong acid may be used, or two or more types of strong acids may be used. The concentration of the strong acid used in the acid treatment is, for example, from 1 to 50 mass%. The acid treatment temperature is, for example, from 70 to 150° C. The duration of the acid treatment is, for example, from 0.1 to 24 hours. In addition, the acid treatment can be performed under reduced pressure, under normal pressure, or under increased pressure. After such an acid treatment, the solid content (containing diamond aggregates) is washed with water through decantation for example. The solid content is preferably repeatedly washed with water by decantation until the pH of the precipitation solution reaches, for example, 2 to 3. If the content of the metal oxide in the diamond particle crude product obtained by the detonation method is small, the acid treatment as described above may be omitted.

### (Oxidation Treatment)

An oxidizing treatment is implemented to remove graphite from the diamond particle crude product using an oxidizing agent. The diamond particle crude product obtained by the detonation method contains graphite, and from among the carbon raw materials such as the carbon released when the explosive that was used underwent partially incomplete combustion, the graphite is derived from the carbon raw material that did not form diamonds. The graphite can be removed from the diamond particle crude product by allowing an oxidizing agent to act on the diamond particle crude product in an aqueous solvent. Furthermore, by allowing the oxidizing agent to act thereon, an oxygen-containing group, such as a carboxy group or a hydroxy group, can be introduced onto the surface of the diamond particles.

Examples of the oxidizing agent used in the oxidation treatment include chromic acid, chromic anhydride, dichromic acid, permanganic acid, perchloric acid, nitric acid, and mixtures thereof, a mixed acid of at least one acid selected therefrom and another acid (for example, sulfuric acid), and salts thereof. Among these, a mixed acid (in particular, a mixed acid of sulfuric acid and nitric acid) is preferably used since such a mixed acid is environmentally friendly and exhibits excellent performance in oxidizing and removing graphite.

The mixing ratio of sulfuric acid to nitric acid (the former/the latter, mass ratio) in the above-described mixed acid is preferably, for example, from 60/40 to 95/5 because when the mixing ratio is in this range, the graphite can be efficiently oxidized and removed at, for example, a temperature of 130° C. or higher (particularly preferably 150° C. or higher, and the upper limit being 200° C., for example), even under a pressure near normal pressure (for example, from 0.5 to 2 atm). The lower limit of the mixing ratio is preferably 65/35, and more preferably 70/30. The upper limit of the mixing ratio is preferably 90/10, more preferably 85/15, and still more preferably 80/20. When the mixing ratio is not less than 60/40, the content of sulfuric acid having a high boiling point is high, and therefore the reaction temperature becomes, for example, 120° C. or higher under a pressure near that of normal pressure, and therefore, the efficiency in graphite removal tends to be improved. When the mixing ratio is less than or equal to 95/5, nitric acid that greatly contributes to oxidation of graphite is contained in a larger amount, and thus efficiency in graphite removal tends to be improved.

The usage amount of the oxidizing agent (in particular, the mixed acid described above) is, for example, from 10 to 50 parts by mass, preferably from 15 to 40 parts by mass, and more preferably from 20 to 40 parts by mass, per 1 part by mass of the diamond particle crude product. In addition, the usage amount of sulfuric acid in the mixed acid is, for example, from 5 to 48 parts by mass, preferably from 10 to 35 parts by mass, and more preferably from 15 to 30 parts by mass, per 1 part by mass of the diamond particle crude product. In addition, the usage amount of nitric acid in the mixed acid is, for example, from 2 to 20 parts by mass, preferably from 4 to 10 parts by mass, and more preferably from 5 to 8 parts by mass, per 1 part by mass of the diamond particle crude product.

Furthermore, when the above-mentioned mixed acid is used as the oxidizing agent, a catalyst may be used together with the mixed acid. When the catalyst is used, the removal efficiency of graphite can be further improved. Examples of the catalyst include copper (II) carbonate. The usage amount of the catalyst is, for example, from about 0.01 to about 10 parts by mass per 100 parts by mass of the diamond particle crude product.

The oxidation treatment temperature is, for example, from 100 to 200° C. The duration of the oxidation treatment is, for example, from 1 to 24 hours. The oxidation treatment can be performed under reduced pressure, under normal pressure, or under increased pressure.

### (Alkali and Hydrogen Peroxide Treatment)

In a case where metal oxides still remain in the diamond particles even after the above-described acid treatment, the diamond particles are in the form of aggregates (secondary particles, cluster diamonds) in which primary particles interact very strongly with each other and aggregate. In this case, an alkali and hydrogen peroxide may be allowed to act on the diamond particles in an aqueous solvent. As a result, the metal oxides remaining in the diamond particles can be removed, and separation of the primary particles from the aggregates can be promoted. Examples of the alkali used in this treatment include sodium hydroxide, ammonia, and potassium hydroxide. In alkali and hydrogen peroxide treatment, the concentration of the alkali is, for example, from 0.1 to 10% by mass, the concentration of hydrogen peroxide is, for example, from 1 to 15% by mass, the treatment temperature is, for example, from 40 to 100° C., and the treatment time is, for example, from 0.5 to 5 hours. Furthermore, the alkali and hydrogen peroxide treatment can be performed under reduced pressure, at normal pressure, or under pressurization.

After the above oxidation treatment or alkali and hydrogen peroxide treatment, it is preferable to remove the supernatant by decantation, for example. In addition, in decantation, the solid content is preferably washed with water. The supernatant liquid from the initial washing with water is colored, and thus, the solid content is preferably repeatedly washed with water until the supernatant liquid becomes visually transparent.

### (Disintegrating Treatment)

The diamond particles may be subjected to a disintegrating treatment as necessary. The disintegrating treatment can be performed using, for example, a high shearing mixer, a high shear mixer, a homomixer, a ball mill, a bead mill, a high pressure homogenizer, an ultrasonic homogenizer, or a colloid mill. It is noted that the disintegration treatment may be performed by a wet process (for example, a disintegration treatment in a state of being suspended in water or the like), or may be performed by a dry process. When the disintegrating treatment is performed by a dry process, drying is preferably performed before the disintegrating treatment. Furthermore, in a case in which the oxidation treatment or the hydrogenation treatment is implemented, the disintegration treatment may be implemented after the oxidation or hydrogenation treatment.

### (Drying)

Drying is preferably implemented after the alkali and hydrogen peroxide treatment. For example, a spray drying apparatus or an evaporator, etc., is used to evaporate the liquid content from the diamond particle-containing solution obtained through the alkali and hydrogen peroxide treatment, after which the resulting residual solid content is dried by being heated and dried in a drying oven. The temperature for heating and drying is, for example, from 40 to 150° C. Through such drying, diamond particles are obtained.

Furthermore, as necessary, the diamond particles may be subjected to an oxidation treatment (for example, oxygen oxidation) or a reduction treatment (for example, a hydrogenation treatment) in a gas phase. By implementing an oxidation treatment in the gas phase, diamond particles having a large amount of C═O groups on the surface are obtained. In addition, by carrying out a reduction treatment in the gas phase, diamond particles having a large amount of C—H groups on the surface are produced.

The diamond particles obtained by the production method described above can be used again as diamond particles that serve as seed crystals in the explosive composition described above.

Each aspect disclosed in the present specification can be combined with any other feature disclosed herein. Each configuration, combinations of them, and the like in each embodiment is an example, and configurational additions, omissions, substitutions, and other changes can be appropriately made within a scope not departing from the spirit of the present disclosure. In addition, each aspect of the invention according to the present disclosure is not limited by the embodiments or the following examples but is limited only by the claims.

### EXAMPLES

An embodiment of the present disclosure will be described in further detail below based on examples.

### Example 1

An explosive composition (approximately 60 g) was produced by adding 10 parts by mass of cluster nanodiamonds (crystallite diameter of primary particles: 4.3 to 4.6 nm) as seed crystals to 100 parts by mass of an explosive component including 2,4,6-trinitrotoluene (TNT) and cyclotrimethylenetrinitramine (RDX) (the mass ratio of TNT to RDX (TNT/RDX) was 60/40). Next, the explosive composition was used to produce an explosive body through the press-loading method.

A production process (detonation) was then implemented to produce nanodiamonds through a detonation method using the explosive body. In this process, an explosive having an electric detonator attached to the molded explosive body was placed inside a pressure-resistant container for detonation, and the container was sealed. The container was made from iron and had a volume of 0.094 m³. Next, the electric detonator was triggered, and the explosive was detonated in the container. Then, the container was allowed to stand at room temperature for 24 hours to lower the temperatures of the container and its interior. After the cooling, a nanodiamond crude product (containing the aggregate of the nanodiamond particles and soot formed in the above detonation method), which adhered to the inner wall of the container, was scraped off with a spatula, and the nanodiamond crude product was thereby collected.

The nanodiamond particle crude product obtained by the detonation described above was then subjected to an oxidation treatment. Specifically, 15 g of the nanodiamond crude product was mixed with 2800 g of a mixed acid of concentrated sulfuric acid and concentrated nitric acid (mass ratio of the concentrated sulfuric acid to the concentrated nitric acid of 11:1) in a precipitation solution (including nanodiamond aggregates) obtained through decantation after an acid treatment, and the mixture was treated for 10 hours at 150° C. Next, the precipitation solution (the solution containing cluster nanodiamonds) obtained through the above-described treatment of washing with water was subjected to drying to obtain a dried powder (cluster nanodiamonds of Example 1). Evaporation to dryness performed with the use of an evaporator was employed as a technique for the drying treatment in the drying.

### Example 2

An explosive composition and an explosive body were produced in the same manner as in Example 1 with the exception that the added amount of the cluster nanodiamonds as seed crystals was 0.5 parts by mass. In addition, similar to Example 1, cluster nanodiamonds of Example 2 were produced by the detonation method using the obtained explosive body.

### Example 3

An explosive composition and an explosive body were produced in the same manner as in Example 1 with the exception that the added amount of the cluster nanodiamonds as seed crystals was 0.1 parts by mass. In addition, similar to Example 1, cluster nanodiamonds of Example 3 were produced by the detonation method using the obtained explosive body.

### Example 4

An explosive composition and an explosive body were produced in the same manner as in Example 1 with the exception that adamantane was used as the seed crystals instead of cluster nanodiamonds. In addition, similar to Example 1, cluster nanodiamonds of Example 4 were produced by the detonation method using the obtained explosive body.

### Example 5

An explosive composition and an explosive body were produced in the same manner as in Example 4 with the exception that the added amount of adamantane as seed crystals was 0.5 parts by mass. In addition, similar to Example 1, cluster nanodiamonds of Example 5 were produced by the detonation method using the obtained explosive body.

### Comparative Example 1

An explosive composition and an explosive body were produced in the same manner as in Example 1 with the exception that cluster nanodiamonds were not added as seed crystals. In addition, similar to Example 1, cluster nanodiamonds were produced by the detonation method using the obtained explosive body.

### Evaluation

The cluster nanodiamond powders obtained in the examples and comparative example were analyzed by X-ray diffraction (XRD), and the crystallite diameters were analyzed by the Scherrer equation. The BET specific surface area of 40 mg of each of the cluster nanodiamond powders was also measured. The results are shown in Table 1. The conditions for X-ray diffraction analysis and BET specific surface area measurements were as follows.

### X-Ray Diffraction Analysis

X-ray diffraction device: Automated Multipurpose X-ray Diffractometer (trade name, available from Rigaku Corporation)

### Measurement of BET Specific Surface Area

High-precision gas/vapor adsorption amount measuring instrument:
BELSORP-mini II (trade name, available from MicrotracBEL Corp.)
Preliminary drying: drying at a temperature of 120° C. for 3 hours in a vacuum
Measurement temperature: -296° C.

TABLE 1

| | Seed Crystal Addition Amount [parts by mass] | XRD Crystallite Diameter [nm] | BET Specific Surface Area [m²/g] |
|---|---|---|---|
| Example 1 | 10 | 7.2 | 257 |
| Example 2 | 0.5 | 7.5 | 200 |
| Example 3 | 0.1 | 7.0 | 224 |
| Example 4 | 10 | 7.1 | 169 |
| Example 5 | 0.5 | 8.9 | 208 |
| Comparative Example 1 | - | 6.7 | 254 |

TABLE 1

| | Seed Crystal Addition Amount [parts by mass] | XRD Crystallite Diameter [nm] | BET Specific Surface Area [m²/g] |
|---|---|---|---|
| Example 1 | 10 | 7.2 | 257 |
| Example 2 | 0.5 | 7.5 | 200 |
| Example 3 | 0.1 | 7.0 | 224 |
| Example 4 | 10 | 7.1 | 169 |
| Example 5 | 0.5 | 8.9 | 208 |
| Comparative Example 1 | - | 6.7 | 254 |

As is clear from Table 1, according to the detonation method, in the cases (Examples) in which nanodiamond particles or adamantanes were added as seed crystals to the explosive composition, large diameter nanodiamond particles were obtained in comparison to the case (Comparative Example 1) in which nanodiamond particles or adamantanes were not added.

Hereinafter, variations of the invention according to the present disclosure will be described.

[Appendix 1] An explosive composition for diamond synthesis, the explosive composition containing: an explosive component, a carbon raw material that may be included as the explosive component, and diamond particles, wherein

a total proportion of the explosive component, the carbon raw material, and the diamond particles relative to a total amount of the explosive composition for diamond synthesis is 99 mass% or greater.

[Appendix 2] The explosive composition for diamond synthesis according to Appendix 1, wherein a crystallite diameter of primary particles of the diamond particles determined by an XRD method is 100 nm or less (preferably 50 nm or less, more preferably 10 nm or less, and even more preferably 7 nm or less).

[Appendix 3] The explosive composition for diamond synthesis according to Appendix 1 or 2, wherein the diamond particles include cluster diamonds.

[Appendix 4] The explosive composition for diamond synthesis according to any one of Appendices 1 to 3, wherein the diamond particles include detonation diamond particles (preferably air-cooled detonation diamond particles).

[Appendix 5] The explosive composition for diamond synthesis according to any one of Appendices 1 to 4, wherein the explosive component includes an explosive component that serves as the carbon raw material.

[Appendix 6] The explosive composition for diamond synthesis according to Appendix 5, wherein the explosive component serving as the carbon raw material includes a compound having a nitro group (preferably, a compound having three or more nitro groups, and more preferably 2,4,6-trinitrotoluene).

[Appendix 7] The explosive composition for diamond synthesis according to any one of Appendices 1 to 6, wherein the diamond particles are contained at an amount of 15 parts by mass or less (preferably 10 parts by mass or less, and more preferably 5 parts by mass or less) per 100 parts by mass of the total amount of the explosive component.

[Appendix 8] The explosive composition for diamond synthesis according to any one of Appendices 1 to 7, wherein the diamond particles are contained at an amount of 0.05 parts by mass or greater (preferably 0.08 parts by mass or greater) per 100 parts by mass of the total amount of the explosive component.

[Appendix 9] The explosive composition for diamond synthesis according to any one of Appendices 1 to 8, wherein the explosive component includes 2,4,6-trinitrotoluene and cyclotrimethylenetrinitramine.

[Appendix 10] The explosive composition for diamond synthesis according to Appendix 9, wherein the mass ratio of 2,4,6-trinitrotoluene to cyclotrimethylenetrinitramine [2,4,6-trinitrotoluene/cyclotrimethylenetrinitramine] in the explosive component is from 30/70 to 95/5 (preferably from 40/60 to 90/10, more preferably from 51/49 to 80/20, and even more preferably from 55/45 to 70/30).

[Appendix 11] The explosive composition for diamond synthesis according to any one of Appendices 1 to 10, wherein a content ratio of the explosive component in the explosive composition relative to the total amount of the explosive composition is 60 mass% or higher (preferably 70 mass% or higher, and more preferably 90 mass% or higher).

[Appendix 12] The explosive composition for diamond synthesis according to any one of Appendices 1 to 11, wherein the total proportion of the total of the explosive component, the carbon raw material, and the diamond particles in the explosive composition relative to the total amount of the explosive composition is 99.5 mass% or higher (preferably 99.8 mass% or higher).

[Appendix 13] An explosive composition for diamond synthesis, the explosive composition containing: an explosive component, a carbon raw material that may be included as the explosive component, and an adamantane, wherein
the explosive component includes 2,4,6-trinitrotoluene and cyclotrimethylenetrinitramine, and
the mass ratio of 2,4,6-trinitrotoluene to cyclotrimethylenetrinitramine [2,4,6-trinitrotoluene/cyclotrimethylenetrinitramine] in the explosive component is from 30/70 to 95/5 (preferably from 40/60 to 90/10, more preferably from 51/49 to 80/20, and even more preferably from 55/45 to 70/30).

[Appendix 14] The explosive composition for diamond synthesis according to Appendix 13, wherein a total proportion of the explosive component, the carbon raw material, and the adamantane relative to the total amount of the explosive composition for diamond synthesis is 99 mass% or higher.

[Appendix 15] An explosive body for diamond synthesis, the explosive body being a compressed filler of the explosive composition for diamond synthesis described in any one of Appendices 1 to 14.

[Appendix 16] An explosive body for diamond synthesis, the explosive body being a compressed filler of an explosive composition containing an explosive component, a carbon raw material that may be included as the explosive component, and nanodiamond particles.

[Appendix 17] An explosive body for diamond synthesis, the explosive body being a compressed filler of an explosive composition containing an explosive component, a carbon raw material that may be included as the explosive component, and an adamantane.

[Appendix 18] A method for producing diamond particles, the method including detonation in which the explosive component in the explosive body for diamond synthesis described in any one of Appendices 15 to 17 is exploded to obtain diamond particles having a larger diameter than that of diamond particles obtained without blending the diamond particles or adamantane as seed crystals.

[Appendix 19] The method for producing diamond particles according to Appendix 18, wherein the diamond particles obtained through the detonation include single crystal diamonds.

1. An explosive composition for diamond synthesis, the explosive composition comprising: an explosive component, a carbon raw material that may be included as the explosive component, and diamond particles, wherein
a total proportion of the explosive component, the carbon raw material, and the diamond particles relative to a total amount of the explosive composition for diamond synthesis is 99 mass% or greater.

2. The explosive composition for diamond synthesis according to claim 1, wherein a crystallite diameter of primary particles of the diamond particles as determined by an XRD method is 100 nm or less.

3. The explosive composition for diamond synthesis according to claim 1, wherein the diamond particles include cluster diamonds.

4. The explosive composition for diamond synthesis according to claim 1, wherein the diamond particles include detonation diamond particles.

5. The explosive composition for diamond synthesis according to claim 1, wherein the explosive component includes an explosive component that serves as the carbon raw material.

6. The explosive composition for diamond synthesis according to claim 5, wherein the explosive component serving as the carbon raw material includes a compound having a nitro group.

7. The explosive composition for diamond synthesis according to claim 1, wherein the diamond particles are contained at an amount of 15 parts by mass or less per 100 parts by mass of the total amount of the explosive component.

8. The explosive composition for diamond synthesis according to claim 1, wherein the explosive component includes 2,4,6-trinitrotoluene and cyclotrimethylenetrinitramine.

9. The explosive composition for diamond synthesis according to claim 8, wherein a mass ratio of 2,4,6-trinitrotoluene to cyclotrimethylenetrinitramine [2,4,6-trinitrotoluene/cyclotrimethylenetrinitramine] in the explosive component is from 30/70 to 95/5.

10. An explosive body for diamond synthesis, the explosive body being a compressed filler of the explosive composition for diamond synthesis described in claim 1.

11. An explosive body for diamond synthesis, the explosive body being a compressed filler of an explosive composition comprising an explosive component, a carbon raw material that may be included as the explosive component, and an adamantane.

12. A method for producing diamond particles, the method comprising detonation in which the explosive component in the explosive body for diamond synthesis described in claim 10 is exploded to obtain diamond particles having a larger diameter than that of diamond particles obtained without blending the diamond particles or the adamantane as seed crystals.

13. The method for producing diamond particles according to claim 12, wherein the diamond particles obtained through the detonation include single crystal diamonds.

14. The explosive composition for diamond synthesis according to claim 2, wherein the diamond particles include cluster diamonds.

15. The explosive composition for diamond synthesis according to claim 2, wherein the diamond particles include detonation diamond particles.

16. The explosive composition for diamond synthesis according to claim 2, wherein the explosive component includes an explosive component that serves as the carbon raw material.

17. The explosive composition for diamond synthesis according to claim 16, wherein the explosive component serving as the carbon raw material includes a compound having a nitro group.

18. The explosive composition for diamond synthesis according to claim 2, wherein the diamond particles are contained at an amount of 15 parts by mass or less per 100 parts by mass of the total amount of the explosive component.

19. A method for producing diamond particles, the method comprising detonation in which the explosive component in the explosive body for diamond synthesis described in claim 11 is exploded to obtain diamond particles having a larger diameter than that of diamond particles obtained without blending the diamond particles or the adamantane as seed crystals.

20. The method for producing diamond particles according to claim 19, wherein the diamond particles obtained through the detonation include single crystal diamonds.
